(19) United States
(12) Patent Application Publication
(10) Pub. No.: US 2025/0374526 A1
(43) Pub. Date: Dec. 4, 2025

(54) HIGH BANDWIDTH MEMORY WITH SUB 4F2 CELLS

(71) Applicant: TAESUNG ENVIRONMENTAL RESEARCH INSTITUTE CO., LTD., Ulsan (KR)

(72) Inventors: Gi Yeol YUN, Ulsan (KR); Seok Man KIM, Ulsan (KR); Chai Rok LIM, Ulsan (KR); Hyeok-Je JEONG, Gimhae-si (KR); Myung-Kon JO, Ulsan (KR)

(73) Assignee: TAESUNG ENVIRONMENTAL RESEARCH INSTITUTE CO., LTD., Ulsan (KR)

(21) Appl. No.: 18/678,912

(22) Filed: May 30, 2024

(30) Foreign Application Priority Data
May 30, 2024 (KR) 10-2024-0071063

(51) Int. Cl. H10B 12/00; H01L 25/065; H10B 80/00

(52) U.S. Cl. CPC H10B 12/482; H01L 25/0657; H10B 12/315; H10B 12/488; H10B 80/00; H01L 2225/06541

(57) ABSTRACT

A semiconductor device, including a plurality of DRAM devices vertically stacked; a through silicon via (TSV) vertically penetrating the plurality of DRAM devices; a conductive pad electrically connecting the plurality of DRAM devices; and a protective layer located on an upper surface of the DRAM device formed to enclose the TSV, wherein the DRAM device includes a substrate; a plurality of bit lines located on the substrate, and disposed parallel to each other in a first horizontal direction at predetermined intervals; a plurality of word lines located on the bit line, and disposed parallel to each other in a second horizontal direction substantially perpendicular to the first horizontal direction at predetermined intervals; a plurality of channel patterns arranged in a honeycomb structure on the bit line; and a gate insulating pattern located between the plurality of channel patterns and the plurality of word lines.

### CROSS REFERENCE TO RELATED APPLICATIONS

This application claims priority to Korean Patent Application No. 10-2024-0071063 filed May 30, 2024, the entire disclosure of which is incorporated herein by reference.

### TECHNICAL FIELD

The present invention relates to a high bandwidth memory comprising a DRAM device. More specifically, the present invention relates to a high bandwidth memory using a DRAM device with sub 4F2 structure comprising a multilayer word line.

### BACKGROUND ART

As the density of semiconductor memory devices increases, the cell structure is changing from 8F2 and 6F2 to 4F2 in order to reduce the area occupied by each unit cell in a planar plane. As such, various methods have been suggested to form components such as transistors, bit lines, word lines, capacitors, etc. in response to the decrease in the area of the unit cell. In particular, in order to implement a 4F2 cell structure, a semiconductor device comprising a vertical channel transistor that induces a vertical channel by disposing a source and a drain vertically has been suggested (non-patent reference 1).

However, in the semiconductor device of non-patent reference 1, the vertical pillar is in direct contact with the cell capacitor, causing leakage current to flow during data storage. Accordingly, the semiconductor device has a short retention time, requiring frequent data refresh operations and high power consumption.

Meanwhile, in the field of semiconductor devices, there has been a continuous progress in the direction of reducing the minimum feature size F and pursuing smaller cell layouts in order to increase the capacity per unit area. Recently, however, the increase in capacity per unit area by reducing the minimum feature size F has reached a physical limitation, and accordingly, it is no longer possible to expect an increase in capacity per unit area by the semiconductor device of non-patent reference 1.

In addition, recently, the semiconductor industry is increasingly demanding high bandwidth and high capacity, and in response thereto, multi-chip stacking technologies are being researched. The bonding process, which is considered to be the most core process of multi-chip stacking technology, is the most representative technology that uses through silicon via (TSV). In the case of bonding chips with TSVs, there may be problems such as chip bending during the bonding process due to the concentration of forces on the TSVs and conductive pads of other chips. In addition, as the temperature rises due to the heat generated during semiconductor operation, the structure may be deformed. Accordingly, researchers are gradually improving and developing TSV technology to solve this problem.

### PRIOR ART REFERENCE

### Non-Patent Reference

(Non-patent reference 1) Chung et al., “Novel 4F2 DRAM Cell with Vertical Pillar Transistor (VPT)” 2011 Proceedings of the European Solid-State Device Research Conference (ESSDERC), 2011

### SUMMARY OF INVENTION

### Technical Task

One of the many objects of the present invention is to provide a vertical channel transistor capable of extending retention time, a DRAM device comprising the same, and a semiconductor package comprising a through electrode.

In addition, another object of the many objects of the present invention is to provide a DRAM device capable of increasing the capacity per unit area and a semiconductor package comprising the same.

### Means for Solving Technical Task

According to an aspect, a semiconductor device, comprising: a plurality of DRAM devices vertically stacked; a through silicon via (TSV) vertically penetrating the plurality of DRAM devices; a conductive pad electrically connecting the plurality of DRAM devices; and a protective layer located on an upper surface of the DRAM device formed to enclose the TSV, wherein the DRAM device comprises: a substrate; a plurality of bit lines located on the substrate, and disposed parallel to each other in a first horizontal direction at predetermined intervals; a plurality of word lines located on the bit line, and disposed parallel to each other in a second horizontal direction substantially perpendicular to the first horizontal direction at predetermined intervals; a plurality of channel patterns arranged in a honeycomb structure on the bit line, the plurality of channel patterns each extending in a vertical direction; and a gate insulating pattern located between the plurality of channel patterns and the plurality of word lines; wherein the plurality of word lines comprise a first word line and a second word line respectively disposed at different heights, and the first and second word lines are provided alternating with each other in the first horizontal direction, and the plurality of channel patterns located on the single bit line are arranged in zigzag along both edges of the single bit line, and the plurality of channel patterns contacting the single word line are arranged in a straight line, is provided.

In an embodiment, at least a portion of each channel pattern may be in direct contact with the substrate.

In an embodiment, each of the plurality of channel patterns may comprise an upper electrode and a lower electrode, and the lower electrode is in contact with the bit line.

In an embodiment, the semiconductor device may further comprise a gate electrode arranged between the word line and the gate insulating pattern.

According to another aspect, a semiconductor package, comprising: a package substrate; an interposer mounted on the package substrate; a processor chip mounted on the interposer; and the semiconductor device mounted on the interposer, spaced apart from the processor chip, is provided

In an embodiment, the semiconductor device and the processor chip may further comprise a physical layer.

### Effect of Invention

The semiconductor device according to an aspect of the present invention suppresses leakage current generation and extends retention time.

In addition, the semiconductor device according to an aspect of the present invention has excellent data retention characteristics and low power consumption.

Furthermore, the semiconductor device according to an aspect of the present invention facilitates the increase in the capacity per unit area and density.

The effects of an aspect of the present specification are not limited to the above-mentioned effects, and it should be understood that the effects of the present specification include all effects that could be inferred from the configuration described in the detailed description of the specification or the appended claims.

### BRIEF DESCRIPTION OF DRAWINGS

FIG. 1 illustrates a semiconductor package comprising a DRAM device, which is an embodiment of the present invention;

FIG. 2 is a perspective view of a vertical channel transistor used in an embodiment of the present invention;

FIG. 3 is a cross-sectional view taken along A-A′ of FIG. 2;

FIG. 4 is a cross-sectional view taken along B-B′ of FIG. 2;

FIG. 5 is a schematic plan view of the vertical channel transistor of FIG. 2;

FIG. 6 is a perspective view of a DRAM device comprising the vertical channel transistor of FIG. 2;

(a) of FIG. 7 is a plan view of a DRAM device comprising a vertical channel transistor with conventional 4F2 structure; and (b) of FIG. 7 is a plan view of a DRAM device comprising a vertical channel transistor wherein (3) the intervals between adjacent word lines are reduced to one-half (½) compared to (1) the width of the word line, (2) the width of the bit line, and (4) the intervals between adjacent bit lines.

### BEST MODE FOR CARRYING OUT THE INVENTION

Hereinafter, an aspect of the present invention will be explained with reference to the accompanying drawings. However, the present invention may be implemented in various different forms, and is not intended to be limited to the embodiments set forth herein.

Throughout the specification, it will be understood that when a portion is referred to as being “connected” to another portion, it can be “directly connected to” the other portion, or “indirectly connected to” the other portion having intervening portions present. In addition, when a member is referred to as being located “on,” “on an upper part of,” “on an upper end of,” “under,” “on a lower part of,” “on a lower end of” another member, this includes not only when a member is adjacent to another member, but also when there is another member between the two members.

Throughout this specification, when a component “includes” an element, unless there is another opposite description thereto, it should be understood that the component does not exclude another element but may further include another element.

The embodiments described herein will be described with reference to the cross-sectional views and/or schematic drawings, which are idealized illustrations of the present invention. In addition, throughout the specification, like reference numerals refer to like components. Detailed descriptions of known features and configurations which may obscure the gist of the present invention are hereby omitted, and each component in each of the drawings illustrating the present invention may be somewhat enlarged or reduced in size for ease of description.

Further, embodiments of the present invention are not limited to specific shapes illustrated, but also include variations in shape produced by the manufacturing process.

Once a semiconductor chip goes through the former process of forming a circuit on a wafer, the later process, which consists of packaging and testing, may be performed. Semiconductor chips have micro-electrical circuits integrated thereon, but the semiconductor chip alone cannot fulfill the role of a semiconductor. The package process provides electrical connections to the outside and protection from the outside environment so that the chip can perform its role. The package also allows the heat dissipated by the semiconductor to be discharged efficiently.

Semiconductor packages may perform roles such as mechanical protection, electrical connections, mechanical connections, and heat dissipation. In other words, a semiconductor chip may be enclosed in a package material such as an epoxy mold component (EMC) to be protected from external mechanical and chemical impact. The package physically and electrically connects the semiconductor chip to the system, and provides power for the semiconductor chip to operate. In addition, the package allows the semiconductor chip to input and output signals to perform its desired function, and allows the semiconductor product to dissipate heat generated during operation.

Semiconductor packaging methods may be categorized into conventional package in which the packaging process is applied to individual chips removed from the wafer, and wafer level package (WLP) in which some or all of the process is performed at the wafer level and later cut into discrete pieces. Early packaging technology followed the lead frame method in which the chip and pad are connected by gold wires. However, as device performance has evolved, the lead frame structure met its limitations, and fBGA (Fine-Pitch Ball Grid Array), which is based on a substrate with a fine pattern, has been applied. Such conventional packages allow many chips to be stacked in a package, and are mainly applied to high-capacity NAND or mobile DRAM.

Recently, WLP, a new method from which the traditional conventional package has evolved, has been introduced to meet the needs of memory products. WLP is a technology well suited for implementing high-performance products and may be packaged in the size of the chip. This minimizes the amount of finished semiconductor products and reduces costs as they do not require materials such as substrates or wires. The WLP process may be utilized for products such as high bandwidth memory (HBM) or computing DRAM, which require high capacity. HBM is a three-dimensional memory semiconductor in which multiple DRAMs are stacked and connected vertically. When semiconductor devices including HBMs are subjected to elevated temperatures, deformation of the substrate may occur. Hereinafter, the semiconductor device and the package of the present invention will be described in detail with reference to the drawings.

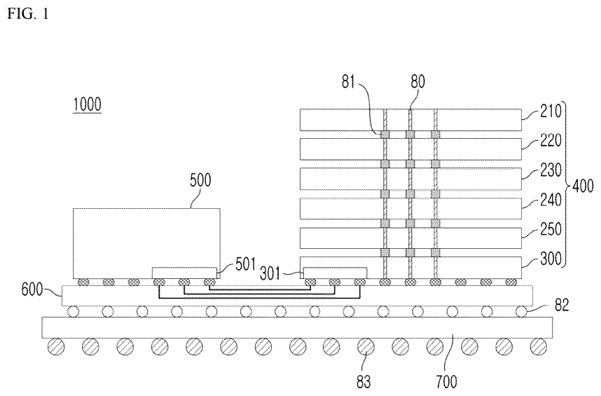

FIG. 1 illustrates a semiconductor package comprising a DRAM device, which is an embodiment of the present invention. Hereinafter, a stacked memory device 400 is described first.

A semiconductor device according to an aspect of the present invention comprises a DRAM device 200; a through silicon via (TSV) 80 vertically penetrating the DRAM device; a conductive pad (not shown) electrically connecting the DRAM device; and a protective layer (not shown) located on an upper surface of the DRAM device formed to enclose the TSV.

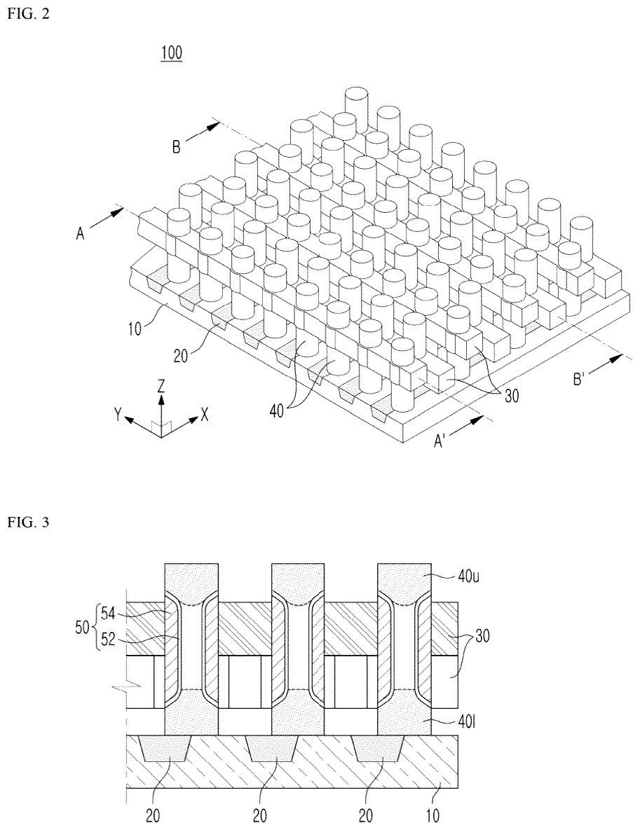

Semiconductor chips 210, 220, 230, 240, 250, 300 may be formed to comprise a DRAM device 200, a TSV 80, a conductive pad, and a protective layer. The DRAM device used in the present invention will be described in the following with reference to FIG. 2 and the following drawings.

The TSV 80 is formed to connect the semiconductor chips 210, 220, 230, 240, 250, 300, such that at least a portion of the TSV 80 provided in the semiconductor chips 210, 220, 230, 240, 250, 300 is formed to vertically penetrate the substrate. For example, the TSV 80 may be formed to protrude from an upper surface of the substrate. The side surface of the protruding TSV 80 may be enclosed and protected by a protective layer (not shown) formed on an upper surface of the substrate.

The TSV 80 may comprise at least one metal. For example, the TSV 80 may comprise a wiring metal layer formed in its center and a barrier metal layer formed on the periphery of the wiring metal layer. The wiring metal layer may comprise one or more of Al, Au, Be, Bi, Co, Cu, Hf, In, Mn, Mo, Ni, Nb, Pd, Pt, Rh, Re, Ru, Ta, Te, Ti, W, Zn and Zr, and the barrier metal layer may comprise one or more stacked structures selected from Ti, Ta, TiN and TaN.

One or more conductive pads (not shown) may be formed on an upper surface or a lower surface of the semiconductor chip 210. For example, an upper conductive pad (not shown) formed on an upper surface of the semiconductor chip 220 may be electrically connected to a semiconductor chip 210 disposed on the semiconductor chip 220, and a lower conductive pad (not shown) formed on a lower surface of the semiconductor chip 220 may be electrically connected to a semiconductor chip 230 disposed below the semiconductor chip 220. Specifically, the upper conductive pad (not shown) may connect the semiconductor chip 220 to the TSV 80 formed within the semiconductor chip 210.

A bump 81 may be interposed between the conductive pad (not shown) and the semiconductor chip 210 to mediate an electrical connection between the conductive pad (not shown) and the semiconductor chip 210. Here, the bump 81 may be a micro bump, but is not limited thereto.

The upper conductive pad (not shown) may be formed on an upper surface of the TSV 80 and may overlap with a portion of the protective layer 202. In other words, a lower surface of the upper conductive pad (not shown) may be in contact with both the upper surface of the TSV 80 and at least a portion of the upper surface of the protective layer 202. In some embodiments of the present invention, the upper conductive pad (not shown) may comprise metal. For example, the upper conductive pad 206 may be a plated pad subjected to plating, and may comprise any one of Au, Ni/Au, and Ni/Pd/Au.

The semiconductor chips 210, 220, 230, 240, 250, 300 may be stacked sequentially in a vertical direction to form a stacked structure, and the stacked structure thus formed may configure a stacked memory device 400. The DRAM device 200 may comprise a memory die, a logic die, a core die, etc. For example, when at least one of the semiconductor chips 210, 220, 230, 240, 250, 300 is a logic chip, at least one of the semiconductor chips 210, 220, 230, 240, 250, 300 may be variously designed according to the operations to be performed. On the other hand, when at least one of the semiconductor chips 210, 220, 230, 240, 250, 300 is a memory chip, the memory chip may be, for example, a non-volatile memory chip, but is not limited thereto. Specifically, the memory chip may be a flash memory chip. The memory chip may be any one of a NAND flash memory chip or a NOR flash memory chip, but is not limited thereto.

The memory chip may comprise any one of a phase-change random-access memory (PRAM), a magneto-resistive random-access memory (MRAM), a resistive random-access memory (RRAM), and a dynamic random-access memory (DRAM). Preferably, the memory chip may be DRAM, but is not limited thereto.

Meanwhile, the semiconductor package 1000 of the present invention may comprise a stacked memory device 400, a processor chip 500, an interposer 600, and a package substrate 700. The stacked memory device 400 may comprise a logic die 300 and core dies 210 to 250.

Each of the core dies 210 to 250 may comprise memory cells for storing data. The logic die 300 may comprise a physical layer 301 and a direct access region (not shown). The physical layer 301 may be electrically connected to the physical layer 510 of a processor chip 500 through an interposer 600. The stacked memory device 400 may receive signals from the processor chip 500 through the physical layer 301, or may transmit signals to the processor chip 500.

The direct access region (not shown) may provide an access path for testing the stacked memory device 400 without going through the processor chip 500. The direct access region may comprise a conductive means for direct communication with an external test device. Test signals received through the direct access region may be transmitted to the core dies 210 to 250 through the TSVs 80. For testing of core dies 210 to 250, data derived from core dies 210 to 250 may be transmitted to a test device through TSVs 80 and the direct access region (not shown). Accordingly, direct access testing of core dies 210 to 250 may be performed.

The logic die 300 and the core dies 210 to 250 may be electrically connected to each other through TSVs 80 and bumps 81. The logic die 300 may receive signals provided to each channel through bumps 81 assigned to each channel from the processor chip 500, or may transmit the signals to the processor chip 500 through the bumps 81. For example, the bumps 81 may be micro bumps.

The processor chip 500 may execute applications supported by the semiconductor package 1000 using the stacked memory device 400. For example, the processor chip 500 may execute specialized operations including at least one processor among a central processing unit (CPU), application processor (AP), graphic processing unit (GPU), neural processing unit (NPU), tensor processing unit (TPU), vision processing unit (VPU), image signal processor (ISP), and digital signal processor (DSP).

The processor chip 500 may control the overall operation of the stacked memory device 400. The processor chip 500 may comprise a physical layer 501. The physical layer 501 may comprise an interface circuit for transmitting and receiving signals to and from the physical layer 301 of the stacked memory device 400. The processor chip 500 may provide various signals to the physical layer 301 of the stacked memory device 400 through the physical layer 501. The signals provided to physical layer 301 may be transmitted to core dies 210 to 250 through interface circuit and TSVs 80 in the physical layer 301.

The interposer 600 may connect the stacked memory device 400 and the processor chip 500. The interposer 600 may connect the physical layer 310 of the stacked memory device 400 and the physical layer 501 of the processor chip 500, and provide physical pathways formed using conductive materials. Accordingly, the stacked memory device 400 and the processor chip 500 may be stacked on the interposer 600 to transmit and receive signals to and from each other.

Bumps 82, 83 may be attached to an upper part and a lower part of the package substrate 700. For example, bumps 82 located on the upper part of the package substrate 700 may be flip-chip bumps, and bumps 83 located on the lower part may be solder balls. The interposer 600 may be stacked on the package substrate 700 through the bumps 82.

The semiconductor package 1000 may transmit and receive signals to and from other external packages or semiconductor devices through the bumps 83. For example, the package substrate 700 may be a printed circuit board (PCB).

FIG. 2 is a schematic perspective view of a vertical channel transistor used in an embodiment of the present invention.

Referring to FIG. 2, a vertical channel transistor 100 used in an embodiment of the present invention comprises: a substrate 10; a plurality of bit lines 20 located on the substrate 10, and disposed parallel to each other in a first horizontal direction at predetermined intervals; a plurality of word lines 30 located on the bit line 20, and disposed parallel to each other in a second horizontal direction substantially perpendicular to the first horizontal direction at predetermined intervals; a plurality of channel patterns 40 arranged in a honeycomb structure on the bit line 20, the plurality of channel patterns each extending in a vertical direction; and a gate insulating pattern (not shown) located between the plurality of channel patterns and the plurality of word lines.

The vertical channel transistor 100 according to an embodiment of the present invention has a plurality of bit lines 20 and a plurality of word lines 30u and 30l intersecting each other. Each bit line 20 may extend in a first horizontal direction (e.g., an X-axis direction), and each word line 30u and 301 may extend in a second horizontal direction (e.g., a Y-axis direction) intersecting the first horizontal direction.

A plurality of channel patterns 40 are disposed at the points where the plurality of bit lines 20 and the plurality of word lines 30u and 30l intersect.

Electrodes (not shown) are formed, respectively, at an upper part and a lower part of the plurality of channel patterns 40. A gate (not shown) is formed to enclose a side surface between the upper electrode and the lower electrode, and the gate may comprise a gate insulating pattern and a gate conducting pattern.

The plurality of word lines 30u and 30l comprise a first word line 30u and a second word line 30l respectively disposed at different heights, and the first and second word lines are provided alternating with each other in the first horizontal direction (e.g., an X-axis direction).

In the conventional vertical channel transistor, the plurality of word lines are disposed side by side at substantially the same height, and thus there are physical limitations to increasing the capacity per unit area.

However, in the present invention, since adjacent word lines are disposed at different heights, the minimum feature size F may be easily reduced, thereby increasing the capacity per unit area and improving the density.

The first and second word lines 30u and 30l may be formed independently of each other of at least one material among metal, semiconductor and alloy, and may be formed of the same material or may be formed of different materials.

A spacer (not shown) may be provided at a side wall of the first and second word lines 30u and 30l. The spacer may prevent contact with other channel patterns 40 which are not interconnected by the first and second word lines 30u and 30l.

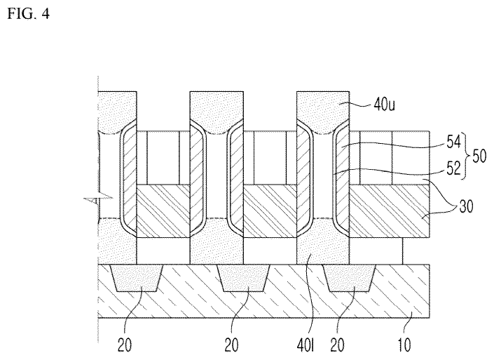

FIG. 3 is a cross-sectional view taken along A-A′ of FIG. 2.

The substrate 10 may include, for example, a group IV semiconductor material such as silicon (Si), germanium (Ge), silicon germanium (SiGe), silicon carbide (SiC), a group III-V semiconductor material such as gallium arsenide (GaAs), indium arsenide (InAs), indium phosphide (InP), an oxide semiconductor, a nitride semiconductor, a nitrogen oxide semiconductor, etc. Specifically, the substrate may be a silicon substrate doped with n-type impurities, but is not limited thereto.

Each of the plurality of channel patterns 40 may extend substantially vertically from the substrate 10. Here, each channel pattern 40 may protrude substantially vertically from an upper surface of the substrate 10. Each channel pattern 40 is integrally formed with the substrate 10, and thus may comprise the same semiconductor material as the substrate 10.

Each of the plurality of channel patterns 40 may comprise a source region as an upper electrode 40u and a drain region as a lower electrode 40l. The lower electrode 40l may be electrically connected to the bit line 20, and the upper electrode 40u may be electrically connected to a capacitor (not shown) which will be described later. The positions of the source region and the drain region may vary as needed, and the upper electrode 40u may function as a drain region and the lower electrode 40l may function as a source region.

In the channel pattern 40, the region between the upper electrode 40u and the lower electrode 40l, which is the body region (not shown), has the same polarity as the substrate 10, and the upper electrode 40u and the lower electrode 40l have a different polarity from the substrate 10. For example, when the substrate 10 is a p-type semiconductor substrate, the body region has a p-type polarity, and the upper electrode 40u and the lower electrode 40l have an n-type polarity. In this case, the upper electrode 40u and the lower electrode 40l may be formed by implanting n-type impurity ions into each of the upper end and the lower end of the channel pattern 40 and performing drive-in diffusion.

A gate 50 is formed between the upper electrode and the lower electrode to enclose a side surface of the channel pattern 40, and the gate 50 may comprise a gate insulating pattern 52 and a gate conducting pattern 54.

In an example, at least a portion of each channel pattern 40 may be in direct contact with the substrate 10. In this case, a back bias may be imparted to each channel pattern 40 to suppress the floating body effect. The contact area of each channel pattern 40 with the substrate 10 is not particularly limited, but may be, for example, any one of a periphery part or a center part of each channel pattern 40.

The bit lines 20 are arranged to extend along a first horizontal direction (e.g., an X-axis direction) on a lower part of the lower electrode 40l, and each bit line 20 may electrically connect the lower electrode 40l arranged along the first horizontal direction. The bit line 20 is formed in the interior of the substrate 10, and thus may comprise the same semiconductor material as the substrate 10.

Each of the plurality of the first word lines 30u is provided at a height corresponding to an upper part of a gate 50 formed on a side surface of the channel pattern 40. Additionally, each first word line 30u may be provided to enclose at least a portion of the upper part of the gate 50.

The first word line 30u may comprise a conductive material. For example, the first word line 30u may comprise at least one of metal, semiconductor and alloy. Specifically, the first word line 30u may comprise one or more metals selected from the group consisting of aluminum, tungsten, molybdenum, titanium, and tantalum, and one or more semiconductors selected from the group consisting of group IV semiconductors, group III-V semiconductors, oxide semiconductors, nitride semiconductors, and nitrogen oxide semiconductors, but is not limited thereto.

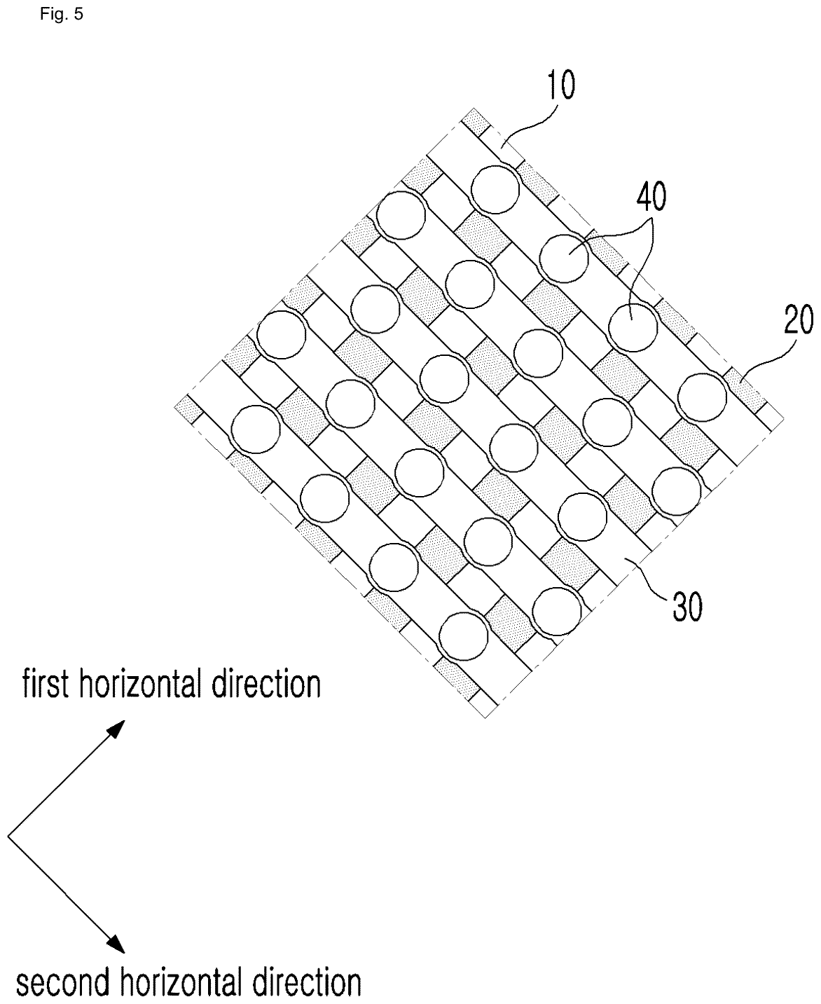

FIG. 4 is a cross-sectional view taken along B-B′ of FIG. 2.

Referring to FIG. 4, the plurality of channel patterns 40 are in common contact with the second word line 30l, and specifically, each second word line 30l is provided at a height corresponding to the lower part of the gate 50 formed on a side surface of the channel pattern 40. Additionally, each first word line 30u is provided to enclose at least a portion of the lower part of the gate 50.

The second word line 30l is disposed at a height different from the first word line 30u when viewed in a vertical cross-section, and specifically, the second word line 30l is disposed at a lower position than the first word line 30u. As such, since adjacent first and second word lines 30u and 30l are disposed at different heights, the minimum feature size F may be easily reduced, thereby increasing the capacity per unit area and improving the density.

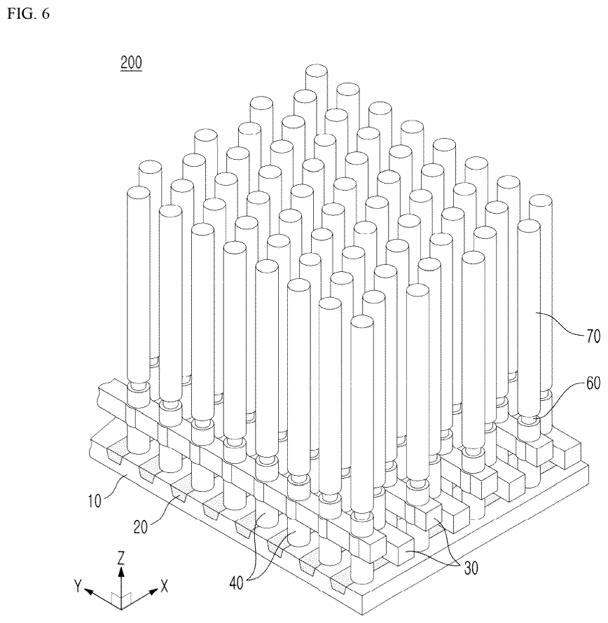

FIG. 5 is a schematic plan view of the vertical channel transistor of FIG. 2.

Referring to FIG. 5, the plurality of channel patterns 40 are disposed in a honeycomb structure on the bit line 20.

Here, a honeycomb structure is a structure in which channel patterns are disposed in the center point and each of the six vertices of a hexagon. Each of the channel patterns located at the six vertices becomes the center point of each of the six neighboring hexagons.

In a honeycomb structure, the hexagon may be an equilateral hexagon, and all six triangles sharing the center point may be equilateral triangles.

As such, as the plurality of channel patterns 40 are disposed in a honeycomb structure, the sub 4F2 structure may be achieved without adjusting the width of the bit line 20, the width of the word lines 30l and 30u, and the intervals between adjacent bit lines 20. For example, assuming that the diameter of each channel pattern 40, the width of the bit line 20, the width of the word lines 30l and 30u, and the intervals between adjacent bit lines 20 are all the same as F, the area of a parallelogram, which is a rectangle connecting the four channel patterns, becomes about) 3.464F2 (=2F×2Fsin60°. As a result, the sub 4F2 structure may be easily achieved without increasing the bit line-to-bit line capacitance, the bit line-to-word line capacitance, and the bit line-to-substrate capacitance, while maintaining the ratio Cb/Cs of bit line capacitance Cb to cell capacitance Cs at the same level as conventionally.

As the plurality of channel patterns 40 have a honeycomb structure, the plurality of channel patterns 40 located on the single bit line are arranged in zigzag along both edges of the single bit line, and the plurality of channel patterns 40 contacting the single word line are arranged in a straight line.

Assuming that the diameter of each channel pattern 40, the width of the bit line 20, and the intervals between adjacent bit lines 20 are all the same as F, the inner half of each channel pattern 40 is located on the bit line 20, and the other half is located on the substrate 10. In this case, since at least a portion of each channel pattern 40 is in direct contact with the substrate 10, a back bias may be imparted to each channel pattern 40 to suppress the floating body effect.

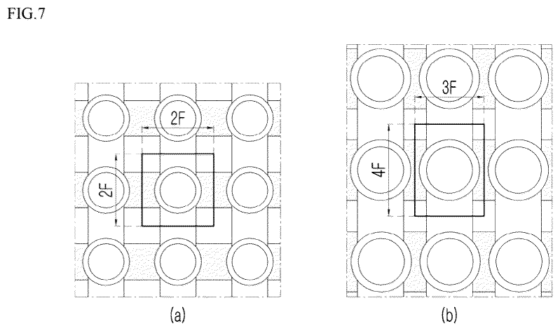

FIG. 6 is a schematic perspective view of a DRAM device comprising the vertical channel transistor of FIG. 2.

Referring to FIG. 6, a capacitor 70 is connected on the vertical channel transistor 100, through which a semiconductor device 200 such as a DRAM may be implemented.

The capacitor 70 may be electrically connected to the channel pattern 40, and a contact plug 60 may be further comprised between the capacitor 70 and the channel pattern 40. The vertical channel transistor 100 may be utilized in a non-memory such as a central processing unit (CPU), as well as in a memory as described above.

The present invention is not particularly limited to methods for manufacturing a vertical channel transistor and a semiconductor device comprising the same, but they may be manufactured by, for example, the following method.

On the substrate 10, a plurality of channel patterns 40 having electrodes 40u and 40l formed at an upper part and a lower part thereof and extending in a substantially vertical direction are formed. The upper electrode 40u of the plurality of channel patterns may be, for example, a source region, and the lower electrode 40l of the plurality of channel patterns may be, for example, a drain region.

The plurality of channel patterns 40 may be arranged in a honeycomb structure on a plane (e.g., an XY plane) perpendicular to the substrate 10.

Next, a gate 50 is formed to enclose a side surface between the upper electrode 40u and the lower electrode 40l of the plurality of channel patterns 40. The gate 50 may comprise a gate insulating pattern 52 and a gate conducting pattern 54. In this case, preferably, the vertical height of the gate 50 is formed to be greater than at least a sum of vertical heights of the first and second word lines 30u and 30l, which will be mentioned later.

Next, a plurality of bit lines 20 are formed to be in common contact with the lower electrode 40l of the plurality of channel patterns 40. Here, the bit lines 20 may be formed in a first horizontal direction (e.g., an X-axis direction), and the plurality of channel patterns 40 located on the single bit line are arranged in zigzag along both edges of the single bit line.

Next, a plurality of first and second word lines 30u and 30l are formed to be in common contact with the gate 50 formed on a side surface of the plurality of channel patterns 40. Here, the first and second word lines 30u and 30l may be formed in a second direction (e.g., a Y-axis direction), and may be provided alternating with each other in a first direction (e.g., an X-axis direction). Each of the first and second word lines 30u and 30l penetrates the center of the plurality of channel patterns 40 arranged in a straight line in the second direction (e.g., a Y-axis direction).

Thereafter, a series of subsequent processes known in the art may be performed one after the other to complete the manufacturing of a vertical channel transistor according to the present invention and a semiconductor device comprising the same.

The technical reasons why the minimum feature size F can be easily reduced as the adjacent word lines are disposed at different heights are described in more details below.

In the field of DRAM devices, the minimum feature size F is an important element in determining the density and performance of a device. The minimum feature size F means the smallest line width which can be drawn within a semiconductor circuit, and is generally the smallest among (1) the width of a word line, (2) the width of a bit line, (3) the intervals between adjacent word lines, and (4) the intervals between adjacent bit lines.

The smaller the minimum feature size F, the higher the transistor density of a semiconductor chip, the smaller the chip size, and the lower the power consumption. Therefore, in the field of DRAM devices, technological advancements have been directed towards adopting the smallest feature size F.

However, such minimum feature size is not something that can be reduced arbitrarily, and is usually determined by the level of technological advancement at the time of manufacturing. Specifically, the minimum feature size can be determined by the resolution capabilities of photolithography equipment, and the quality and performance of the photoresist.

(a) of FIG. 7 is a plan view of a DRAM device comprising a vertical channel transistor with conventional 4F2 structure. In (a) of FIG. 7, (1) the width of the word line, (2) the width of the bit line, (3) the intervals between adjacent word lines, and (4) the intervals between adjacent bit lines are all set to F, resulting in a 4F2 structure.

(b) of FIG. 7 is a plan view of a DRAM device comprising a vertical channel transistor wherein (3) the intervals between adjacent word lines are reduced to one-half (½) compared to (1) the width of the word line, (2) the width of the bit line, and (4) the intervals between adjacent bit lines. In this case, (3) the intervals between adjacent word lines become the minimum feature size F, and this minimum feature size F is determined by the level of technological advancement at the time of manufacturing, resulting in an increase in the area of unit cell (12F2=4F×3F). In other words, it is never preferable to adjust the intervals between adjacent word lines in order to reduce the area of unit cell.

However, in the present invention, the horizontal interval between the adjacent first word lines and second word lines can be adjusted to any extent when the interval between adjacent first word lines and the interval between adjacent second word lines each has a minimum feature size F or greater. This is because word lines formed in different planes (different heights) are formed in different processes, and thus not affected by the minimum feature size, which is determined by the technology level at the time of manufacturing. In theory, it is possible to adjust the horizontal interval between the adjacent first word lines and second word lines up to ½F.

Therefore, the DRAM device according to an aspect of the present invention may achieve an improved capacity per unit area compared to the capacity per unit area which can be generally achieved at the level of technical progress at the time of manufacturing.

The foregoing description of the present specification has been presented for illustrative purposes, and it is apparent to a person having ordinary skill in the art that the present specification can be easily modified into other detailed forms without changing the technical idea or essential features of the present specification. Therefore, it should be understood that the forgoing embodiments are by way of example only, and are not intended to limit the present specification. For example, each component which has been described as a unitary part can be implemented as distributed parts. Likewise, each component which has been described as distributed parts can also be implemented as a combined part.

The scope of the present specification is presented by the accompanying claims, and it should be understood that all changes or modifications derived from the definitions and scopes of the claims and their equivalents fall within the scope of the present specification.

### DESCRIPTION OF REFERENCE NUMERALS

10: substrate
20: bit line
30: word line
40: channel pattern
40l: lower electrode
40u: upper electrode
50: gate
52: gate insulating pattern
54: gate conducting pattern
60: contact plug
70: capacitor
80: through silicon via (TSV)
81, 82, 83: bump
100: vertical channel transistor
200: DRAM device
210, 220, 230, 240, 250: core DRAM die
300: logic die
301: physical layer
400: stacked memory device
500: processor chip
501: physical layer
600: interposer
700: package substrate
1000: semiconductor package

What is claimed is:

1. A semiconductor device, comprising:
a plurality of DRAM devices vertically stacked;
a through silicon via (TSV) vertically penetrating the plurality of DRAM devices;
a conductive pad electrically connecting the plurality of DRAM devices; and
a protective layer located on an upper surface of the DRAM device formed to enclose the TSV,
wherein the DRAM device comprises:
a substrate;
a plurality of bit lines located on the substrate, and disposed parallel to each other in a first horizontal direction at predetermined intervals;
a plurality of word lines located on the bit line, and disposed parallel to each other in a second horizontal direction substantially perpendicular to the first horizontal direction at predetermined intervals;
a plurality of channel patterns arranged in a honeycomb structure on the bit line, the plurality of channel patterns each extending in a vertical direction; and
a gate insulating pattern located between the plurality of channel patterns and the plurality of word lines;
wherein the plurality of word lines comprise a first word line and a second word line respectively disposed at different heights, and the first and second word lines are provided alternating with each other in the first horizontal direction, and
the plurality of channel patterns located on the single bit line are arranged in zigzag along both edges of the single bit line, and the plurality of channel patterns contacting the single word line are arranged in a straight line.

2. The semiconductor device of claim 1, wherein at least a portion of each channel pattern is in direct contact with the substrate.

3. The semiconductor device of claim 1, wherein each of the plurality of channel patterns comprises an upper electrode and a lower electrode, and the lower electrode is in contact with the bit line.

4. The semiconductor device of claim 1, further comprising a gate electrode arranged between the word line and the gate insulating pattern.

5. A semiconductor package, comprising:
a package substrate;
an interposer mounted on the package substrate;
a processor chip mounted on the interposer; and
the semiconductor device of claim 1 mounted on the interposer, spaced apart from the processor chip.

6. The semiconductor package of claim 1, wherein the semiconductor device and the processor chip further comprise a physical layer.
